(19) United States
(12) Patent Application Publication
(10) Pub. No.: US 2011/0241744 A1
(43) Pub. Date: Oct. 6, 2011

(54) LATCH-BASED IMPLEMENTATION OF A REGISTER FILE FOR A MULTI-THREADED PROCESSOR

(75) Inventors: Mayan Moudgill, White Plains, NY (US); Gary Nacer, Morris Plains, NJ (US); Shenghong Wang, Yorktown Heights, NY (US)

(73) Assignee: Aspen Acquisition Corporation, San Diego, CA (US)

(21) Appl. No.: 13/061,106

(22) PCT Filed: Aug. 20, 2009
(86) PCT No.: PCT/US09/54421

§ 371 Date: Jun. 14, 2011

Related U.S. Application Data
(60) Provisional application No. 61/092,654, filed on Aug. 28, 2008.

(51) Int. Cl. H03K 3/289

(52) U.S. Cl. 327/202

(57) ABSTRACT

A processor register file for a multi-threaded processor is described. The processore register file includes, in one embodiment, T threads, having N b-bit wide registers. Each of the registers includes a b-bit master latch, T b-bit slave latches connected to the master latch, and a slave latch write enable connected to the slave latches. The master latch is not opened at the same time as the slave latches. In addition, only one of the slave latches is enabled at any given time. As should be apparent to those skilled in the art, T, N, and b are all integers. Other embodiments and variations are also provided.

### CROSS-REFERENCE TO RELATED APPLICATION(S)

The present application is a PCT Patent Application that relies for priority on U.S. Provisional Patent Application No. 61/092,654, filed on Aug. 28, 2008, the contents of which are incorporated herein by reference.

### FIELD OF THE INVENTION

The invention concerns a latch-based implementation for a high-port register file. This implementation is optimized for use in a low-power, multi-threaded digital signal processor (“DSP”) or other processor.

### DESCRIPTION OF THE RELATED ART

Traditionally, register files have been implemented using memory bit-cell structures. These bit-cell implementations are generally a good solution. However, since most vendors supply register-files which can support only a limited number of read and write ports, high-port designs become too large or impractical for low-power applications. For these high-port applications, it then becomes necessary to perform custom implementations or utilize flop-based structures.

These custom implementations present a number of difficulties, as should be appreciated by those skilled in the art. Specifically, prior art custom implementations are not particularly efficient from a power-consumption standpoint.

Accordingly, there is a desire in the art for a solution to the implementation that is at least more energy efficient.

### SUMMARY OF THE INVENTION

It is, therefore, one aspect of the invention to provide a register file for a multi-threaded processor that is more efficient, at least in terms of energy consumption, than register files in the prior art.

It is another aspect of the invention to provide a processor register file for a multi-threaded processor with T threads, having N b-bit wide registers. Each of the registers includes a b-bit master latch, T b-bit slave latches connected to the master latch, and a slave latch thread write enable connected to the slave latches. The master latch is not opened at the same time as the slave latches. In addition, at most one of the slave latches is enabled at any given time. As should be apparent to those skilled in the art, T, N, and b are all integers.

It is also contemplated that the register file of the invention is designed such that the master latch opens when a clock signal reaches a predetermined clock level. In this embodiment, it is contemplated that the slave latches open when a slave latch enable signal reaches a predetermined slave latch enable level that is complimentary to the predetermined clock level. This can be obtained by connected the slave latch enable to the complement of the clock. Note that the slave latch thread write enable signal must also be asserted to select a slave latch to be opened.

The invention also is contemplated to encompass an embodiment where the master latch writes in response to a write enable signal that is separate from the slave latch enable signal. Here, the master latch is open only if the clock signal reaches the predetermined clock level and the write enable signal is true.

The register file also may be configured such that the write enable signal clock-gates the predetermined clock level.

In addition, the slave thread write enable signal may gate the slave latch enable level that is complimentary to the predetermined clock level.

An additional embodiment of the register file contemplates the inclusion of additional features such as R read ports. The read ports include N T-to-1 b-bit wide slave muxes connected to the slave latches that select ones from outputs of the slave latches for each register. The read ports also include R N-to-1 b-bit wide muxes connected to the slave muxes that select ones from outputs of the slave muxes. As may be appreciated, R is an integer.

In another embodiment contemplated to fall within the scope of the invention, a processor register file for a multi-threaded processor is provided. The processor register file has T threads, N b-bit wide registers, and W write ports. The processor register file includes W b-bit master latches and N slave latch groups. The slave latch groups encompass T b-bit slave latches and are connected to the master latches. The register file also includes N W-to-1 select muxes connected to the slave latch groups, one for each of the slave latch groups. The select muxes select from the master latches and generate outputs connected to corresponding ones of the slave latches in the slave latch groups and their corresponding selects. The register file also includes N thread latch enables, one for each of the slave latch groups, such that each of the thread latch enables enables at most one of the latches in the corresponding group. Associated ones of the master latches and slave latches are not opened at the same time.

Another contemplated embodiment of the invention encompasses a processor register file for a multi-threaded processor with T threads, having N b-bit wide registers, W write ports, and a loop-back write port. The register file includes W b-bit regular master latches and N slave latch groups, encompassing T b-bit slave latches, connected to the regular master latches. The register file also includes N b-bit loop-back master latches, with one loop-back master latch corresponding to each slave latch group. In addition, the register file includes N W+1-to-1 b-bit select muxes, one for each slave latch group. The select muxes select from the regular master latches and the loop-back master latches and generate output connected to each of the b-bit slave latches in a corresponding one of the slave latch groups. Next, the register file includes N T-to-1 b-bit loop-back muxes, one for each of the slave latch groups. One from the loop back muxes selects between the slave latches in one from the slave latch groups and writes to a corresponding loop-back latch. The register file also includes N thread write latch enables, one for each of the slave latch groups. Each of the thread write latch enables enables at most one of the slave latches in a corresponding one from the slave latch groups. In this arrangement, master and slave latches are never open at the same time. As should be apparent, T, N, b, and W are all integers.

In a variation, it is contemplatd that a first additional logic is positioned between at least one loop-back master latch and at least one select mux.

It is contemplated that the first additional logic may be adapted to select from the loop-back master latches and the regular master latches to establish a W+1 b-bit input for at least one of the select muxes.

In another contemplated variation, a second additional logic may be placed between at least one loop-back mux and at least one loop-back master latch.

The second additional logic may be adapted to select from an output of multiple ones of the loop-back muxes to form the N b-bit inputs to the loop-back master latches.

### BRIEF DESCRIPTION OF THE DRAWINGS

Various embodiments of the invention will be described in connection with the figures appended hereto, in which:

FIG. 1 is a circuit schematic of a first embodiment of a register file according to the invention;

FIG. 2 is a circuit schematic of a second embodiment of a register file according to the invention;

FIG. 3 is a circuit schematic of a third embodiment of a register file according to the invention;

FIG. 4 is a circuit schematic of a fourth embodiment of a register file according to the invention;

FIG. 5 is a circuit schematic of a fifth embodiment of a register file according to the invention;

FIG. 6 is a circuit schematic of a sixth embodiment of a register file according to the invention;

FIG. 7 is a circuit schematic of a seventh embodiment of a register file according to the invention;

FIG. 8 is a circuit schematic of a eighth embodiment of a register file according to the invention;

FIG. 9 is a circuit schematic of a ninth embodiment of a register file according to the invention; and

FIG. 10 is a circuit schematic of a tenth embodiment of a register file according to the invention.

### DESCRIPTION OF PREFERRED EMBODIMENT(S) OF THE INVENTION

While the invention is described in connection with various examples and embodiments contemplated for use with the invention, the invention is not intended to be limited solely to the embodiments and variations discussed herein. To the contrary, the invention is intended to encompass equivalents and variations, as would be appreciated by those skilled in the art.

Before discussing the various embodiments of the invention, a brief discussion of a basic flop-based design is discussed. Using the basic design as a starting point, the invention then will be discussed in connection with improvements upon the basic example, both in terms of area and in terms of power consumption.

The design of the first embodiment of the invention is an improvement on what is referred to as the SB3500. The SB3500 is also referred to as the “Sandblaster,” as should be appreciated by those skilled in the art.

For the embodiment most commonly envisioned, the invention contemplates use of a four (4)-threaded processor. The vector register file for the first embodiment is an eight (8)-entry file, where seven (7) of the registers may be read and six (6) of the registers may be modified in any given cycle.

More specifically, this embodiment of the invention is a four (4)-way multi-threaded sixteen (16)-wide SIMD (Single Instruction, Multiple Data) architecture targeted at digital signal processing application. The SIMD unit employs four 8-entry 32-byte register files, with one (1) register context per thread. With one register per thread, there are thirty-two 32-byte registers.

The invention (e.g., the SB3500), is a LIW (Long Instruction Word) which can execute a load or store in the same cycle as a SIMD operation. A SIMD operation may specify three (3) source registers and two (2) target registers. To obtain peak (or at least optimized) performance on a wide-SIMD DSP (Digital Signal Processor), the invention supports SIMD-register pair rotation and SIMD-register shifts. This results in up to seven (7) registers being read and six (6) registers being written to every cycle.

The invention involves a SIMD register file. By exploiting certain optimization opportunities available because of multi-threading and by basing the design on a latch-based construction rather than a flip-flop-based construction, a synthesized register file with a sub-1 ns access time in 0.65 mm² is contemplated to be possible. With respect to this embodiment, it is estimated that a flop-based construction would occupy twice the area of the latch-based construction of the invention. It is also contemplated that the SIMD register file may be implemented, at least in one specific instance, in 0.24 mm² with a sub 1-ns access time in the TSMC 65LP process (Taiwan Semiconductor Manufacturing Company Limited's 65 nm LP (low-power) CMOS process). Clearly, this area is smaller that the prior embodiment.

Since the discussion of a four (4)-way multi-threaded processor with an eight (8)-entry, thirty-two (32)-byte register file is complex, the discussion of the invention has been simplified. Specifically, reference initially is made to a register file having two (2) threads, four (4) entries, two (2) write ports, and three (3) read ports. As should be appreciated by those skilled in the art, the invention is not limited to these specific parameters. The invention may be applied to register files with a greater number of threads and with larger vector files.

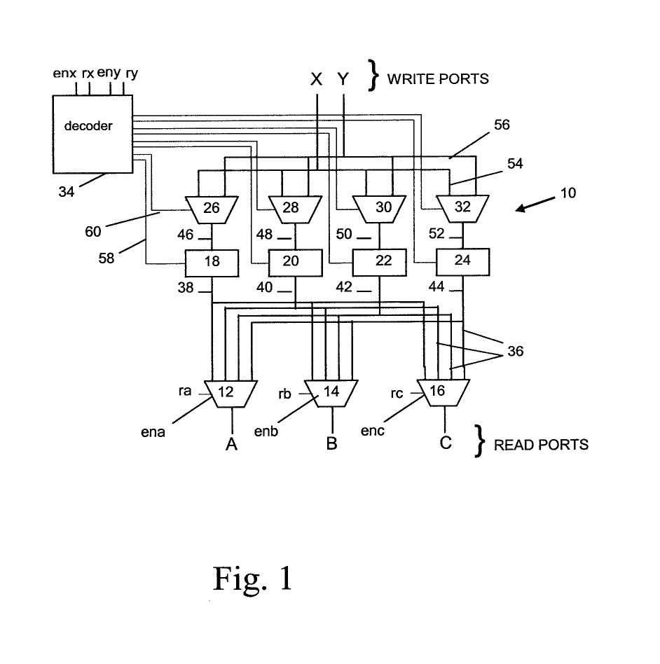

Referring to FIG. 1, and in the context of the simplified discussion mentioned above, the first embodiment of the register file 10 includes two (2) write ports, which are labeled X and Y. The register file also includes three (3) read ports, which are labeled A, B, and C. The corresponding register names for the read ports and the write ports are ra, rb, re, rx, and ry. As should be apparent, information is intended to be read by the read ports A, B, C and written to the write ports X, Y.

The write ports X, Y include enables, which indicate that the corresponding port is active (or enabled for capturing data). The enables are referred to as enx and eny. Additionally, for power control, enables may be included for the read ports. These power control enables are referred to as ena, enb, and enc.

Further, as noted above, a two-threaded processor is illustrated. In certain implementations, exactly one thread will access the register file for writing, and one thread will access the register file for reading at any one time. These are identified by counters, which are labeled as the wrid and the rdid, respectively. In the examples provided, the counters are 1-bit.

To assist with the discussion that follows, and as noted above, there are several variables to keep in mind. The number of threads is designated “T”. “N” refers to the number of entries in the register. The bit size is referred to as “b”. The number of write ports is designated as “W”. Finally, the number of read ports is designated “R”. T, N, b, W, and R are all integers.

For the simplified example defined above, the following values for these variables may assist with an understanding of one or more embodiments of the invention. Specifically, T=2, N=4, b=1, W=2, and R=3. Of course, as should be apparent to those skilled in the art, other values for T, N, W, R, and b may be employed without departing from the scope of the invention.

### Flop-Based to Multi-Threaded Latch-Based Register File

With reference to FIG. 1, a register file 10 based on a straight-forward flop design is illustrated for a single thread. From a generic perspective, the flip-flop-based register file 10 includes N entries of b bits, with W write-ports and R read-ports.

As illustrated in FIG. 1, the register file 10 includes the following components: (1) three read muxes (also referred to as “multiplexers”) 12, 14, 16, (2) four flip-flops 18, 20, 22, 24, (3) four write muxes 26, 28, 30, 32, (4) one decoder 34, (5) three read ports A, B, C, and two write ports X, Y.

As should be appreciated by those skilled in the art, the decoder 34 is nothing more than a combination of one or more demuxes (also referred to as “demultiplexers”). In this case, the decoder 34 incorporates two (2) demuxes, each with four outputs. For simplicity of the drawings, however, the decoder 34 is illustrated as a single component.

Additionally, as also should be appreciated by those skilled in the art, each flip-flop 18, 20, 22, 24 is merely the combination of two flops or latches. As with the decoder 34, to simplify the drawings, the flip-flops 18, 20, 22, 24 are illustrated as single components.

As noted above, the simplified invention is based upon a register file having two (2) threads, four (4) entries, two (2) write ports, and three (3) read ports. Accordingly, the values, as noted above, are as follows: T=2, N=4, b=1, W=2, and R=3.

While these values define the simplified example of the invention, a generic model for a register file may be defined using the same variables. Specifically, for a generic design for a register file, the components are contemplated to include: (1) a number, N*b, of flip-flops (such as flip flops 18, 20, 22, 24) with enables to implement each register, (2) a number, W, of N-output demuxes (such as the decoder 34) to enable a flip-flop for every write port (such as write ports X, Y), (3) a number, N*b, of W−1 muxes (such as the write muxes 26, 28, 30, 32) to allow each register to select between the write ports, and (4) a number, R*b, of N−1 muxes (such as the read muxes 12, 14, 16) to select the correct register.

For definitional purposes, N*b is intended to refer to the product of the values of N and b. Similarly, R*b is the product of R and b. As such, in the simplified example of the invention, since N=4 and b=1, N*b=4. In this example, R=3 and b=1. Therefore, R*b=3.

Also for definitional purposes, the label “W−1” refers to the construction of a mux where the mux includes W outputs from one input. The label “N−1” is intended to refer to a mux with N outputs from one input. In the simplified example of the invention, W=2. Therefore, the write muxes 26, 28, 30, 32, each of which have one input and two outputs, are W−1 muxes. To complete the example, since N=4 in the simplified example of the invention, an “N−1 mux” is intended to refer to one of the read muxes 12, 14, 16, each of which have one input and four outputs.

If the register file is designed for use in a multi-threaded processor with T threads, one contemplated implementation is to use an N*T entry register file. A thread identifier may be employed to enable/select specific ones of the registers when writing/reading. N*T is the product of values for N and for T.

FIG. 1 illustrates the components of the register file 10, which is illustrated in accordance with the simplified guidelines discussed above. The register file 10 includes three read ports A, B, C. Each of the read ports A, B, C are connected to a read multiplexer (or read mux) 12, 14, 16. The read muxes 12, 14, 16 are N−1 muxes, meaning that they each have one input (one of A, B, or C) and N outputs. The outputs are provided with reference number 36. Each of the four outputs 36 connect to inputs 38, 40, 42, 44 of the flip-flops 18, 20, 22, 24. As noted, ra, rb, and rc refer to the register names. The enables ena, enb, enc for each of the read muxes 12, 14, 16 are also illustrated.

The construction of the four flip-flops 18, 20, 22, 24 should be apparent to those skilled in the art. Therefore, a detailed discussion of the flip-flops 18, 20, 22, 24, 26 is not provided here. The flip-flops 18, 20, 22, 24 each include an output 46, 48, 50, 52, which are connected to four write muxes 26, 28, 30, 32. The outputs from the flip-flops 18, 20, 22, 24 are the inputs to the write muxes 26, 28, 30, 32.

The write muxes 26, 28, 30, 32 each have two outputs 54, 56 that connect to the two write ports X, Y. The write muxes 26, 28, 30, 32 are W−1 muxes, as defined above.

FIG. 1 also illustrates the decoder 34, the write enables enx, eny, and the registers rx, ry. The decoder 34 connects to the flip-flops 18, 20, 22, 24 via communication links 58. The decoder 34 connects to the write muxes 26, 28, 30, 32 via communication links 60. The communication links 58, 60 supply enables for these components. As such, the decoder 34 has eight outputs, as illustrated. As should be appreciated by those skilled in the art, and as discussed above, the decoder 34 includes two 4-output demuxes to enable the flip-flop for every write port. According to the generic example, therefore, the decoder 34 incorporates the number, W, of N-output demuxes.

As is apparent in the illustration, the read muxes 12, 14, 16 each have one input and four outputs 36. Each of the write muxes 26, 28, 30, 32 has a single input 46, 48, 50, 52 and two outputs 54, 56, one for each write port X, Y. As noted above, and as should be apparent to those skilled in the art, the number of outputs 36, 54, 56 depends on a variety of different parameters associated with the register file. Accordingly, the specific numbers illustrated in FIG. 1 are not intended to be limiting of the invention.

### Optimization #1: Write-Master, Register-Slave Latch

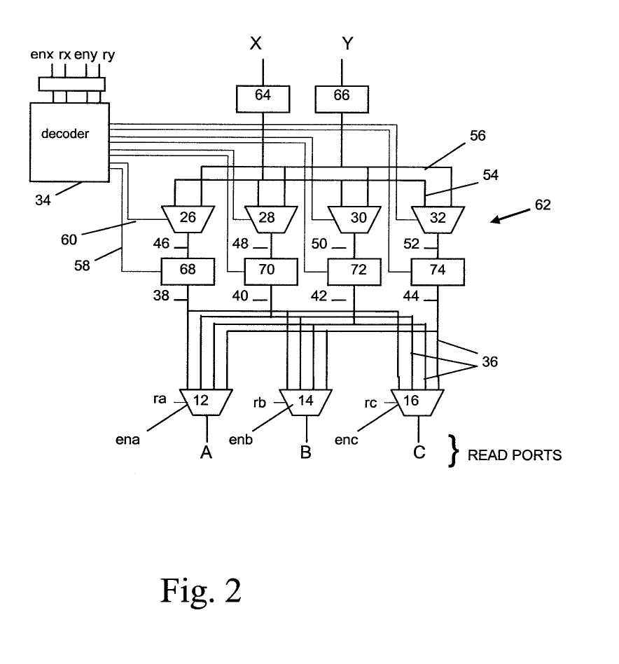

FIG. 2 illustrates one possible optimization of the register file 10 illustrated in FIG. 1. As with FIG. 1, the illustration encompasses a single thread. The optimization illustrated in FIG. 2 results in the register file 62. In the register file 62, several latches are employed according to the following general parameters: (1) the data is captured for each write port X, Y separately using a number, W*b, master latches 64, 66, (2) a number, N*b, of W−1 muxes 26, 28, 30, 32 are used to select between the write data, and (3) a number, N*b, of slave latches 68, 70, 72, 74 are used to capture the data.

In this embodiment, the master latches 64, 66 are referred to as the first set of latches and the slave latches 68, 70, 72, 74 are referred to as the second set of latches. As should be appreciated by those skilled in the art, the first and second set of latches must not pass data through at the same time. One simple way of accomplishing this is by having the first and second sets of latches driven by the same clock. In this contemplated construction, one of the two sets of latches should be active high while the other set is active low.

As should be apparent when comparing the first embodiment of the register file 10 with the second embodiment of the register file 62, the master/slave flip-flops 18, 20, 22, 24 have been replaced with master latches 64, 66 and slave latches 68, 70, 72, 74.

In the generic example, the master latches 64, 66 and the slave latches 68, 70, 72, 74 are provided. The master latches 64, 66 capture any write data, and the slave latches 68, 70, 72, 74 hold the register state.

While somewhat of a simplification of the modification between the register file 62 and the register file 10, the master/slave flip-flops 18, 20, 22, 24 may be considered as two latches. Accordingly, by modifying the register file 10 to create the register file 62, essentially, a replacement has been made of (N+N)*b latches with (W+N)*b latches. For the simplified embodiment, (N+N)*B=(4+4)*1=8 and (W+N)*b=(2+4)*1=6. Therefore, there are two less latches in the register file 62 than in the register file 10. Among other contemplated advantages, this improves operational speed and reduces power consumption.

### Optimization #2: Write-Mux Sharing for Multi-Threads

As should be appreciated by those skilled in the art, in a T threaded processor, a number, T*N, of registers are provided. If any register may be written in any cycle, optimization becomes impossible. However, if the multi-threaded processor is organized such that at most one thread's registers will be written in a cycle, then the T registers for each of the N entries may share the same write-port select muxes, such as the write muxes 26, 28, 30, 32. With sharing, additional savings in power consumption and additional increases in efficiency are realized. As should be apparent to those skilled in the art, with sharing, the number of write-select muxes may be reduced from N*T*b to just N*b W−1 muxes.

Further, since only the writes for one of the threads may be active at any time, the decode logic is only slightly larger than that required for N registers. As may be appreciated, an additional block is needed to generate T enable lines, and each of the W write enables generated by the decode block must be AND'ed with each of the T thread enables to generate the T*N register enables.

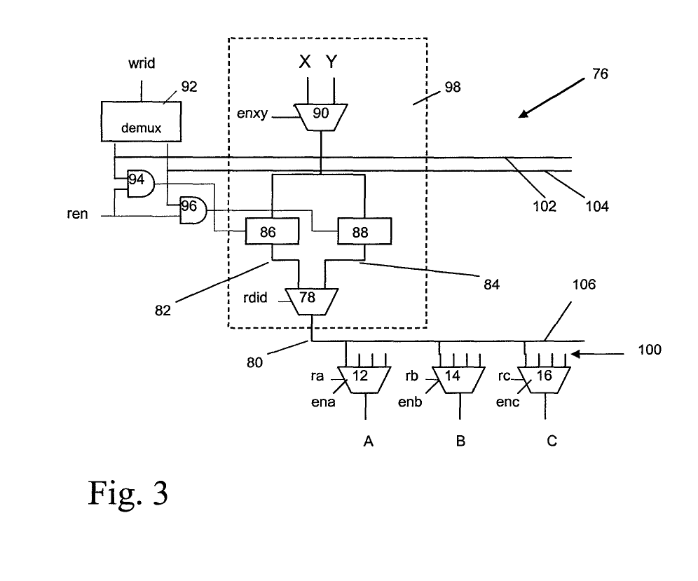

Having described the generic example of this embodiment, reference is now made to FIG. 3, which illustrates the register file 76 according to this embodiment. FIG. 3 illustrates the read ports A, B, C and their associated read muxes 12, 14, 16. Signals from the read muxes 12, 14, 16 are provided to a secondary read mux 78, which is provided with a read counter enable rdid. The secondary read mux 78 has a single input 80 and dual outputs 82, 84. The outputs 82, 84 are connected to latches 86, 88. The latches 86, 88 connect to a write mux 90 that connects to the write ports X, Y. The write mux 90 includes an enable enxy, as shown. The write mux 90 is a mux shared by the two write ports X, Y.

FIG. 3 also illustrates a decoder 92, which may be a demux or a combination of several demuxes. The decoder 92 is connected to a write counter signal wrid. Two AND gates 94, 96 are connected between the decoder 92 and the latches 86, 88. The AND gates 94, 96 assist with generation of the register enables.

In FIG. 3, a repetitive portion 98 of the logic is encompassed by a dotted line. The repetitive portion 98 captures the portion of the logic that is repeated a number of times, N, depending on the number of outputs 100 from the read muxes 12, 14, 16. Each of the outputs 100, therefore, are contemplated to be connected to a separate repetitive portion 98. The communication links 102, 104, 106 that are illustrated in FIG. 3 are intended to connect to the remaining three iterations of the repetitive portions 98 that are not illustrated.

### Optimization #3: Read-Mux Sharing for Multi-Threaded

A fourth variation on the register file design focuses on read-mux sharing. In general, in a T threaded processor, each of the read ports A, B, C select between N*T sources. This selection, therefore, requires a number, R*b, of N*T-to-1 muxes. If it is assumed that X-to-1 muxes are implemented using X-1 2-to-1 mux primitives, then a total number, (N*T−1)*R*b, of 2-to-1 muxes are required.

However, if the multi-threaded processor's organization is such that, at most, the registers of one thread are read in any given cycle, then the read-mux select logic may be simplified. This implementation may be performed using two (2) stages of muxing: (1) a first stage including a number, N*b, of T-to-1 muxes (to select the register for the active thread), (2) a second stage including a number, R*b, of N-to-1 muxes (to select the register for each port). Normalizing using 2-to-1 muxes results in a total number, N*b*(T−1) +R*b*(N−1), of 2-to-1 muxes, for a comparative savings of a number, (R−1)(T−1)N*b, of 2-to-1 muxes. Where R=3, T=2, and N=4, a savings of 8*b muxes is achieved. When b=1, 8 fewer muxes may be used in this contemplated embodiment of the invention.

This particular embodiment is not illustrated since it is merely a modification of the embodiment illustrated in FIG. 3, as should be appreciated by those skilled in the art.

### Loop-Back

In certain contemplated embodiments, a loop back may be desired. For example, a processor, in addition to all its other operations, may read a register, performs some simple modification to the values read from the register, and write the modified values back to the same register. To implement this simple operation, separate read and write ports may be added to the register-file. If it is necessary for the processor to support M such operations per cycle, M additional read and write ports may be added to the register. Of course, with the addition of each read and write port, associated read and write muxes also must be added.

As may be appreciated by those skilled in the art, adding M additional read ports, M additional write ports, and M additional read and write muxes (i.e., shared read and write muxes) increases the complexity of the register file. To avoid this complexity, it is contemplated to replicate the logic N times. In such a case, each of the N registers feed into its own copy of the logic required for the operation. The N write select muxes in such an embodiment would have an additional input (i.e., they would become W+1 to 1 muxes), as should be appreciated by those skilled in the art.

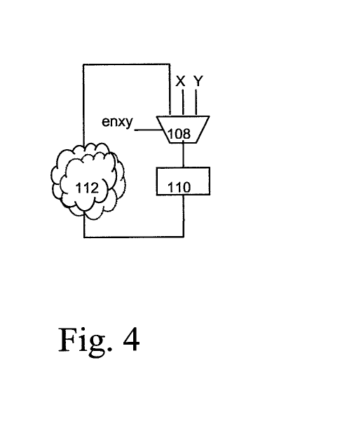

A simple example of this concept is provided in FIG. 4. Here, a write mux 108 is connected to a latch 110. A processor 112 acts on data from the register via a predetermined function. The function itself is not relevant to practice of the invention. After the processor 112 creates the output data, the output data is inputted into the write mux 108, as illustrated.

While the exact function in the loop-back is not critical to the invention, potential loop-back functions may include: (1) one or more register shifts, where the value of the register is shifted by one or more fixed amounts, and/or (2) a read-modify-write operation, where the new value is the result of muxing in the original register contents with some set of new values. This second function also may be implemented by using additional write-enable signals, one for each sub-range of the register that is to be modified/unaltered.

### Master-Slave Split Registers

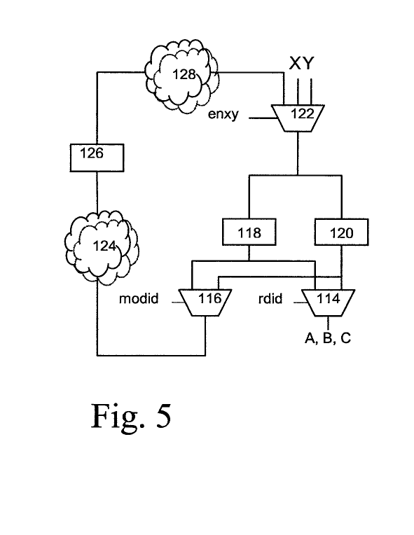

FIG. 5 combines the loop-back concept together with the master/slave latch implementation illustrated in FIG. 2. In such a case, as illustrated in FIG. 5, an additional master latch is needed in the feed back path. As should be appreciated by those skilled in the art, this removes any potential savings from the splitting. However, if the processor is multi-threaded, and only the registers for one thread are written in a cycle, then the additional cost is one master latch and a T−1 mux for every one of the N registers (i.e., one extra master latch per T slave latches).

The combinatorial logic that implements the loop back function can be organized so that it is done between the slave-latch and the master-latch, or between the master-latch and the slave-latch, or split so that some of the work is done before and some done after the master latch. Depending on the function and how the combinatorial logic is partitioned, it is possible that the loop-back master latch 96 will be of a different size than the registers themselves.

Before turning to other variations contemplated by the invention, it is noted in FIG. 5 that the illustrated circuit combines features from FIGS. 2 and 4 together. In FIG. 5, the registers A, B, C feed into a shared read mux 114. The shared read mux 114 is connected, in parallel, with a loop demux 116. The shared read mux 114 connects to two latches 118, 120. The latches 118, 120, in turn, connect to a shared write mux 122. The output from the loop demux 116 passes through a processor 124, the master latch 126, and another processor 128 (at least in this example) before being fed into the shared write mux 122, as discussed above.

### Other Variations

With respect to the embodiments including master-slave registers, there is logic between the master write-data/loop-back latches and the slave latches. This includes write-select muxes and part of the loop-back function. As a result, it is possible that additional logic and/or operations may be implemented in this path. The following discussion provides details for further variations and embodiments contemplated to fall within the scope of the invention.

### Power Control

To conserve power, the selected implementation should operate so that as few bits as possible change every cycle. When referring to a register-file, the register-names and the thread-ids are included in the group of items where as few bits as possible should be changed. This means that, if a port is not being used, it is prudent to hold, as stable, the register name(s) (and thread-id((s)). To accomplish this, read-enable signals and write-enable signals are provided.

### Write Thread-ID Latching

As noted, to conserve power, it is prudent to change as few bits as possible in each cycle. As should be appreciated by those skilled in the art, one of the controls feeding the register enables in a multi-threaded processor is the thread id. If the thread-id changes every cycle, this change will cause some switching, even without a write occurring. Consequently, it is prudent to save the thread-id in a register and to use that saved value to drive the write-enable decode.

If there are multiple write-ports, two options are available: (1) the thread-id may be saved once, or (2) a thread-id may be saved for each write-port. When only a copy of the thread-id is saved, the thread id must be changed if a write is to occur. If there are multiple write ports, but only one is changed, then there will be needless switching in the enable logic for the other write ports. Needless switching consumes power needlessly. Needless switching may be avoided, however, if one copy of the thread-id is retained by each write port. In such a case, the saved thread-id of a port is only changed when the port is active so that switching happens only when necessary.

Of course, other cases are contemplated where it is prudent to share a saved thread-id among two or more write ports. For example, if two write ports are always, or almost always, enabled at the same time, using only one saved thread-id provides the same power savings. In addition, one less register is required. In this contemplated embodiment, if a split write-master/register-slave latch implementation is used (FIG. 2), the saved thread-ids may be saved by the latches themselves, not by the flip-flops.

### Read Thread-ID Flopping

Similar to the write operations described above, for minimization of switching on the read-select muxes, the thread-id (or thread-ids) may be saved in a register. Moreover, as noted above, the thread-ids should be changed only if necessary. In this contemplated embodiment, minimization of switching depends on the organization of the register file or files. In a straight-forward implementation, the thread-id needs to be saved once, once per read-port, or a variation of these two schemes (e.g., once or once per read port).

However, if the design described under the header “Optimization #3”, above, is used, the muxes controlled by the thread-ids are distinct from the read port. As should be apparent, the N*b T−1 muxes may be driven either from the same saved thread-id or from one of up to N saved thread-ids. If N thread-ids are saved, a new thread-id is loaded into the thread-id save register every time the corresponding register is accessed.

### Additional Embodiments

Additional embodiments of the invention also are contemplated. These additional embodiments involve both code-based and hardware-based variations that provide a variety of operational improvements.

The invention, which encompasses the SB3500 (discussed above), is based upon a load/store long-instruction-word (LIW) architecture. It includes four (4) basic units—branch, integer, memory and SIMD. When functioning, the LIW may issue three (3) operations. The operations may be issued separately from each unit. For instance, a single instruction may issue a load or store memory operation, a SIMD operation, and a branch operation in the same instruction. Of course, one unit may issue more than one operation, where practicable.

The various units may have separate register files, as is contemplated for at least one embodiment of the invention. Of course, the various units may share a common register file, as should be appreciated by those skilled in the art.

In one embodiment, the memory and integer units are contemplated to share a single, sixteen (16)-entry, four (4)-byte, general purpose register file. In this embodiment, the SIMD unit may include several register files, including an eight (8)-entry, thirty-two (32)-byte, SIMD register file and a four (4)-entry, eight (8)-byte, accumulator register file. These files are allocated on a per-thread basis since the invention is contemplated to be four (4)-way threaded. As a result, there are four (4) copies of all of the registers.

The SIMD register file may be a load/store target. If so, the SIMD register file is expected to require one (1) read port and one (1) write port. As should be appreciated by those skilled in the art, certain SIMD operations may require three (3) source operations and two (2) target operations. Additional read/write ports may be needed to implement DSP algorithms in a wide SIMD processor, as should be appreciated by those skilled in the art.

### Shift/Rotate

It is contemplated that the invention may permit shift/rotate functionality. The concept and objective of shift/rotate functionality should be understood by those skilled in the art. In digital signal processing terms, the canonical algorithm employed for a shift/rotate operation is the FIR (Finite Impulse Response) filter. The FIR filter may be expressed as set forth below in Code Segment #1:

Code Segment #1

for( i=0; i<M; i++ )

int sum = 0
for( j=0; j<N; j++ )

sum += x[i+j] * c[j];

y[i] = sum>>16;

In Code Segment #1, N is generally considered to be small. It is noted that, in a DSP, the arrays involved typically may be two (2)-byte, fixed point numbers. If so, the sum is expected to be a four (4)-byte, fixed point number. Additionally, in this instance, the operation is expected to have saturating, fixed point semantics.

The invention is contemplated to include a sixteen (16)-way SIMD multiply-and-reduce operation, rmulreds act, va, vb. The multiply-and-reduce operation reads two (2) SIMD registers, va, and vb, treats the two registers as containing sixteen (16) two (2)-byte fixed point values, multiplies the values together, and sums the products with four (4) bytes of an accumulator register act. In pseudo-code, the behavior of the multiply-and-reduce operation may be expressed as shown below in Code Segment #2:

Code Segment #2

for( i=0; i<16; i++)

act += va[i]*vb[i]

As above, the multiply and add operations have fixed point semantics.

Using this instruction, the inner loop for a typical filter might require as few as one (1) SIMD operation. Of course, it is also contemplated that this instruction also may require a greater number of SIMD operations. In the case where a single SIMD operation is employed, it is contemplated that the other operations in the body of the outer loop may become important. For instance, the inner loop may be structured to compute a series of scalar results that are assembled into a vector. This idiom may be repeated in other DSP algorithms. To optimize this feature, the invention may include a rshift0 vt, aca, 0 operation to shift the contents of the accumulator into a SIMD register and clear the accumulator. The rshift0 vt, aca, 0 operation may be expressed, as set forth in Code Segment #3, below.

Code Segment #3

for( i=0; i<15; i++)

vt[i] = vt[i+1];

vt[15] = aca>>16;
aca = 0;

Data reuse opportunities are expected to differ from a matrix-vector product. In the FIR filter, one array, c, may be held constant. However, it is contemplated that successive iterations of the outer loop may be configured to reuse all but the first element of x from the previous iteration, shifted by one position. This type of data-use pattern is common to other DSP algorithms, as should be apparent to those skilled in the art. To optimize this idiom, the invention treats even/odd pairs of SIMD registers as though they were a shift register with a loop-back. Using a rrot ve, 0 operation, the thirty-two (32), two (2)-byte elements in the two register files may be rotated by one position. The rrot ve, 0 operation may be expressed as set forth in Code Segment #4 below.

Code Segment #4

ve0 = ve[0]
vo0 = vo[15]
for( i=0; i<15; i++)

ve[i] = ve[i+1];
vo[i+1] = vo[i];

ve[15] = vo15;
vo[0] = ve0;

For Code Segment #4, it is intended for sixteen (16) elements, which may be designated as x[0 . . . 15], to be loaded in a register, which may be labeled vr2. The next elements, which may be designated as x[16 . . . 31], may be loaded in reverse order into a pair register, labeled as vr3. (It is noted that there exists a load-vector-reversed instruction, lrr, which loads the 16 bytes in a reversed order.) After each iteration of the outer loop, the rrot operation is used to rotate vr2 and vr3 by one position (e.g., one position over) so as to maximize reuse.

### Register Ports

With respect to the invention (e.g., the SB3500), it is contemplated that, for a FIR filter, with N=16, the body of the outer loop may be written according to Code Segment #5, below:

Code Segment #5

| | |
|---|---|
| rmulreds | %ac0,%vr2,%vr4 |
| rrot | %vr2,0 |
| rshift | %vr0,%ac0,0 |

As should be apparent to those skilled in the art, of these three (3) operations, two (2) are used to move data around. Only one of these operations is, involved in any type of computation. Consequently, the invention includes complex operations that combine one or more computations with shifts and rotations. For example, the above behavior may be accomplished via a single operation using a single rmulreds operation, which is expressed as set forth below in Code Segment #6:

### Code Segment #6

rmulredslr 0,% ac0,% vr2,% vr4

These examples demonstrate rotation and shifts of data by two (2) bytes. There are other operations which rotate/shift data by four (4) or eight (8) bytes as well. These other operations also are contemplated to fall within the scope of the invention.

To optimize hardware, the shift and rotate directions of a register are fixed. As in the rrot example above, even registers shift only in one direction and odd registers shift only in the other direction. By convention, it is said that even registers shift/rotate down, while odd registers shift/rotate up. In a rotation, the lowest element of the even register gets shifted into the lowest position of its odd register pair, while the highest element of the odd register gets shifted into the highest position of the even register.

There are operations that combine three (3) source registers and two (2) target registers with rotation and shifting. Combined with a simultaneous load or store, these operations result in a peak utilization of seven (7) register values being read and six (6) register values being modified per cycle.

### Multi-Threading

The invention encompasses a four (4)-way multi-threaded processor (e.g., the SB3500). Consequently, the invention is intended to replicate all architected states four (4) times, with one copy for each thread.

The pipeline of the invention (e.g., the SB3500 pipeline) is set up so that the SIMD register for stores and the SIMD operations from exactly one thread are read on any one cycle, and the SIMD registers for exactly one thread are written on any given cycle. During the cycle, the rotates and shifts are read before they are written.

### Implementation

A straight-forward design that satisfies the requirements of the SIMD register file in the invention results in a thirty-two (32) entry, two hundred fifty-six (256) bit register-file with seven (7) read and six (6) write ports. If this structure were to be implemented in an ASIC (Application-Specific Integrated Circuit) flow, the high port requirements would force the structure to be synthesized out of flip-flops and multiplexes. As such, the structure would require: (1) 8K (32×256) flip-flops for the storage, (2) 8K (32x256) 6-to-1 multiplexes for the write ports, and (3) 1.75K (7×256) 32-to-1 multiplexes for the write ports. Obviously, such a structure would require a large area. However, by taking advantage of the constraints of the architecture of the invention (e.g., the Sandblaster SB3500), the combination of pipelining together with a latch-based implementation makes it possible to reduce the area by more than half.

### Shift/Rotate Ports

In a design that uses three (3) read/write ports for shifts and rotates, any register may be read, shifted/rotated, and then written back to any other register. However, in the architecture of the invention, shifts and rotates are defined in a much more restricted fashion—a shifted/rotated register reads its own contents and moves the data two (2), four (4), or eight (8) bytes. Further, the value that is shifted into the vacated positions comes from: (1) an accumulator in the case of a shift, or (2) a paired register in the case of a rotate.

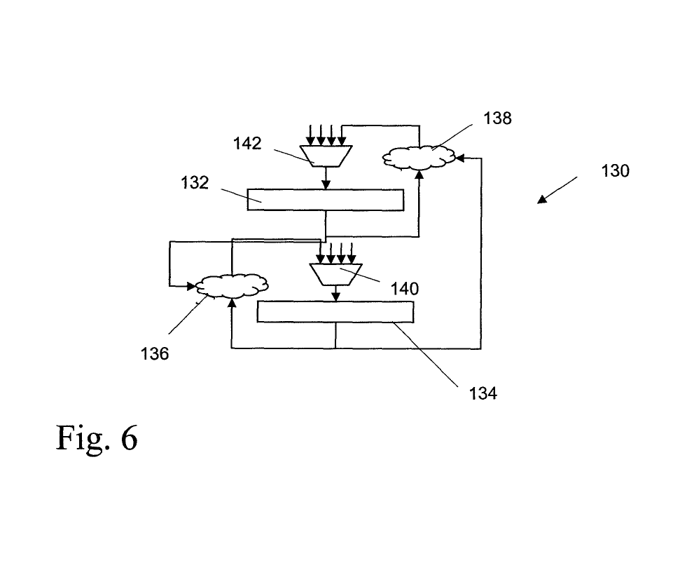

This arrangement suggests an alternative implementation that is contemplated for the invention. Specifically, the shift/rotate logic(s) may be replicated for each register. As may be seen in FIG. 6, there are no read ports for the shift/rotate operation—each register 132, 134 is directly connected to the shift/rotate logic 136, 138 for shifting and to its pair for rotate in values. Instead of three (3) ports for shift/rotate, each register 132, 134 has one write port for the result of the shift/rotate logic.

With reference to FIG. 6, the shift/rotate circuit 130 includes a first register 132 and a second register 134. The first register 132 and the second register 134 are connected to one another via first and second shift/register logics 136, 138, respectively. The first and second shift/register logics 136, 138 are connected, in turn, to first and second muxes 140, 142, which are connected to the first and second registers 132, 134. As illustrated in FIG. 6, the shift/rotate circuit 130 effectively defines a two-part loop to facilitate the shift/rotate operation.

At first glance, it would appear that three (3) read-ports and two (2) write-ports have been removed at the cost of having thirty-two (32) copies of the shift/rotate logic instead of three (3). However, as shall be seen below, only need eight (8) copies are needed.

### Register Groups

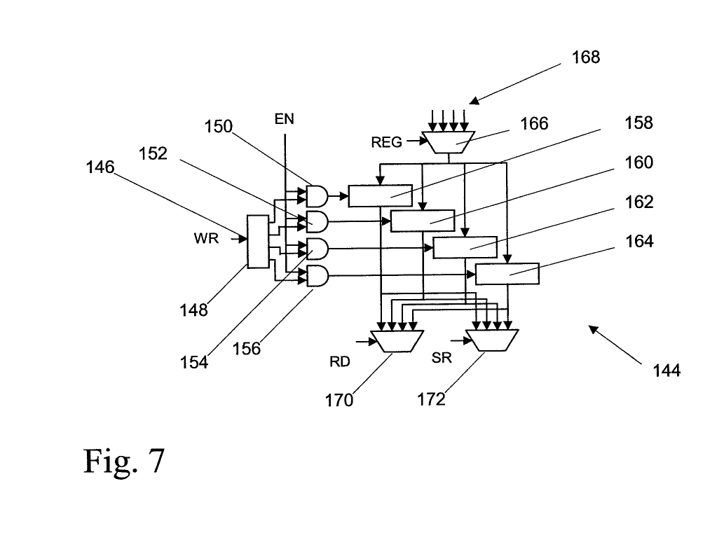

Reference is now made to FIG. 7 and FIGS. 8-10. As indicated above and by way of further introduction, it is noted that each thread has eight (8) registers—vr0 through vr7. There are four (4) instances of each register, one for each thread. We call the four per-thread instances of a register a register-group. For example, the vr3 register-group consists of the four (4) registers, the vr3 registers for each thread.

It is noted that FIG. 7 presents an embodiment of the invention that is, in some respects, a variation of the embodiment illustrated in FIG. 3. In FIG. 7, the register file or circuit 144 includes an input 146 that selected one from a plurality of registers for a current thread. The currently active thread is designated WR in FIG. 7. The input 146 provides data to a decoder 148. The decoder, in turn, is operationally connected to four (4) AND gates 150, 152, 154, 156. Each AND gate 150, 152, 154, 156 also received an enable signal EN, as shown. In addition, each AND gate 150, 152, 154, 156 is connected to a latch 158, 160, 162, 164.

The latches 158, 160, 162, 164 not only receive signals from the AND gates 150, 152, 154, 156, they also receive signals from a 4-to-1 mux 166. As is immediately apparent from the data flow, the 4-to-1 mux 166 is a demultiplexer or demux. The 4-to-1 mux 166 receives signals from four ports 168 to select the register, REG, associated with the currently active thread.

From the latches 158, 160, 162, 164, signals are routed to a first demux 170 and a second demux 172. The first and second demuxes 170, 172 also are 4-to-1 muxes, like the 4-to-1 mux 166. The first demux 170 addresses the active read thread, RD. The second demux addresses the active shift/rotate thread 172.

The pipeline in the invention is organized so that the registers of only one of four (4) threads are written in any given cycle. Specifically, only one (1) register in a register-group may be written in any one cycle, and that register is selected by the currently active thread, WR. Consequently, only one (1) input is needed to select a multiplex per register-group, as opposed to one per register.

Further, the pipeline of the invention is organized so that only the registers of one thread are read in any one cycle for SIMD execution or storing. This allows a two-stage output select structure to be employed. For this two-stage structure, each of the register-groups first selects the output of the register for the active read thread, RD. This is then fed into an 8-1 multiplex for each read port.

The timing of the reads for the shift/rotates is contemplated to differ from the timing for the other read ports. Consequently, there is expected to be a second set of 4-to-1 multiplexes controlled by the active shift/rotate thread SR, that select the register input to the shift/rotate logic. This allows us to use one copy of the shift/rotate logic per register-group, instead of one per register.

### Latch

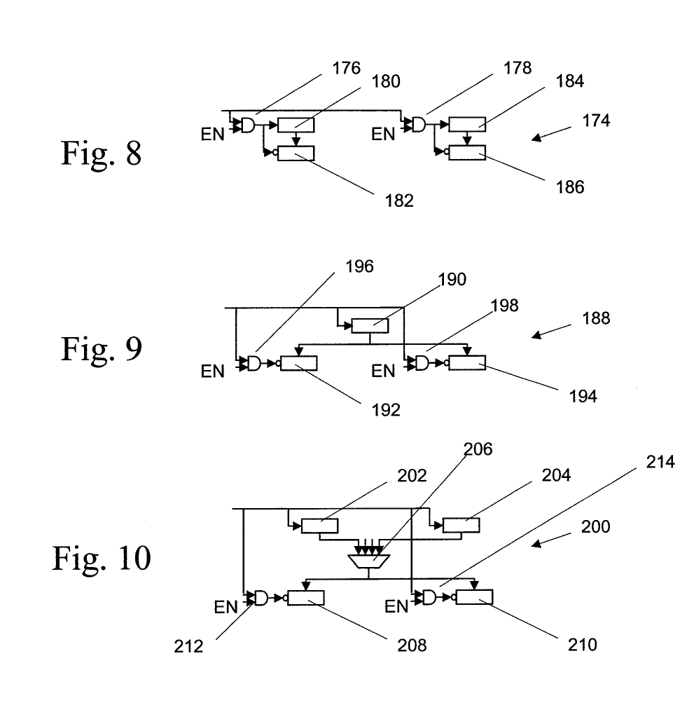

Reference is now made to FIGS. 8 to 10.

A rising-edge-triggered D flip-flop may be implemented using two (2) transparent D latches, where a change in the value is first captured in the pass-low master latch, and then transferred to the pass-high slave latch. If the registers in a register-group are implemented using master-slave flip-flops, it is contemplated that four (4) master latches and four (4) slave latches may be employed in a particular register group, as shown in FIG. 8.

As illustrated in FIG. 8, the partial register-group circuit 174 encompasses first and second AND gates 176, 178. The first AND gate 176 provides output signals to a first master latch 180 and a first slave latch 182. Similarly, the second AND gate 178 provides input to a second master latch 184 and a second slave latch 186. The first master latch 180 provides input to the first slave latch 182. Similarly, the second master latch 184 provides input to the second slave latch 186. The latches 180, 182, 184, 186 all may be transparent D latches, as indicated above. Other variations also are contemplated to fall within the scope of the invention.

By separating out the enables for the master latches and the slave latches, it is possible to implement the partial register-group circuit 188 shown in FIG. 9. Thus, it is possible to implement the register-group structure using one (1) master latch and four (4) slave latches (two of which are illustrated), as shown in FIG. 9. Writing is controlled by enabling the appropriate slave latch (i.e. the one for the active write thread) for the register-group.

FIG. 9 illustrates the partial register-group circuit 188 that includes a master latch 190 connected to first and second slave latches 192, 194. As in the prior example, the slave latches 192, 194 are connected to AND gates 196, 198 that receive enables.

With returned reference to FIG. 7, the master latch is fed by a 4-to-1 multiplex to select between the various input ports. By swapping the multiplex and the master-latches, it becomes possible to capture the four values to be written at the rising edge of the clock. Then, the appropriate value may be selected using the 4-to-1 multiplex, and captured by the slave latch at the falling edge of the clock, as shown in FIG. 10.

With reference to FIG. 10, a partial register-group circuit 200 is illustrated. Here, master latches 202, 204 provide input to a 4-to-1 mux 206. Output from the 4-to-1 mux 206 are provided to slave latches 208, 210. The slave latches 208, 210, in turn, receive input and enables from AND gates 212, 214.

It is noted that the partial register-group circuit 200 illustrated in FIG. 10 replaces eight (8) master-latches with eleven (11) master latches—three (3) for the normal write ports plus one (1) for each register group for the shift/rotate values. This particular arrangement assists with timing, as should be apparent. The circuit design 200 also moves logic from the final execute/write-back stage of the pipeline, where timing is tight, to the register read stage, which possesses extra processing capacity or “slack.” As a consequence of implementing this approach, it is contemplated that the delay from the master latches to the slave latches may be reduced by almost one half of a cycle. In another contemplated variation, the delay is reduced by almost one half of a cycle. By reducing the delay, it becomes possible to use the clock as a control for the latches without sacrificing speed.

### Shift/Rotate Logic

As described above, each register-group has a 4-to1 output multiplex for selecting the value that is to be shifted/rotated. After being shifted/rotated, the shifted/rotated value is captured in a per-register-group master latch.

In this arrangement, the shift rotate logic is considered to be fairly straight-forward. In the case of an even register, for the first one hundred ninety-two (192) bits, the even register consists of a 4-to-1 multiplex that selects between the bit, bit+16, bit+32 and bit+64 of the register.

For the last sixty-four (64) bits, the structure is more complicated. In the last sixty-four (64) bits, the values provided by the last sixty-four (64) bits of the paired odd register are treated as a contiguous value. At each position, the logic selects between the bit, bit+16, bit+32 and bit+64. Rotation is defined to allow swapping of sixteen (16) bit values while wrapping around registers. This may entail selection of select bit+48 in some instances. Finally, for shifts, the new value may be provided by the accumulator. Consequently, up to a 6-to-1 multiplex is needed.

The shift logic for odd registers is similar, except that the selects are from negative bit positions, and rotates use the bits from the first sixty-four (64) bits of the paired even register.

### Structure

According to one embodiment of the invention, the final structure may include: (1) 2.75K (11×256) master latches for the inputs, (2) 2K (8×256) 4-to-1 in select multiplexes, (3) 8K (32×256) slave latches to hold values, (4) 4K (2×8×256) 4-to-1 register-group output multiplexes, and (5) 4K (4×256) 8-to-1 read-port output select multiplexes. Additionally, for the shift/rotates, the register file adds about (1) 1.5 K (8×192) 4-to-1 multiplexes for the internal shift and (2) 0.5K (8×64) 6-to-1 multiplexes for the terminal shift/rotate. Assuming that all multiplexes are implemented using 2-to-1 multiplexes, the implementation uses 10.75K latches and 53K 2-to-1 latches to implement a 8 Kb register file as well as the shift/rotate function.

### Power Minimization

Among other objectives, the invention is designed for low power operation. One way to achieve this objective is to consider power savings with respect to the SIMD register file.

For example, gated clocks may be employed for both the slave latches and the master latches. The enable to each slave latch may be controlled a clock-gate for the clock for that latch. Additional clock-gate control logic may be employed so that if a write port is not active, the clock to that master latch is held high.

It is understood that care should be taken to minimize the amount of switching in the multiplexes. This means that the multiplex controls for each register group, which are in separate registers, are modified only when necessary. Specifically, the WR, RD and SR active thread multiplex controls are stored in separate registers for each register group. Only if a register in that register-group is to be written, read or shifted/rotated should the value of the corresponding multiplex control register be updated to the actual active thread.

Similar precautions are contemplated to be taken for the shift/rotate controls. The shift/rotate multiplex-select controls may be stored on a per-register-group basis, and only updated when a register in that register-group is shifted/rotated.

Finally, the multiplex-select controls for read-port output select multiplexes are contemplated to be stored in a register. This register may be modified only when that read-port is active.

In a narrower data-path, replicating the controls and adding the logic to selectively update them may not result in a power savings. However, with a two hundred fifty-six (256) bit wide data-path, it is expected that considerable amounts of power will be saved.

In one embodiment, it is anticipated that the register file may be implemented in the TSMC65LP (65 nm 1.2V low-power) process, using the standard TSMC library, in a standard AISC design flow. Such an embodiment may be synthesized from VHDL by RTL compiler through the standard Cadence-based tool-flow.

The final area of the SIMD register file (after place and routing) in the invention has been found to be approximately 0.65 mm². It is noted that this is the total area, including the logic for the shift/rotates and power control. Of course, other areas are contemplated to fall within the scope of the invention.

The power, as reported by PowerMeter, for a test that sustains two (2) reads and three (3) shift/rotates per cycle at 600 MHz, with almost all bits flipping between reads, is 160 mW. With respect to this measurement, the total core and chip power, as reported by PowerMeter, was validated against the actual chip and it was found that the numbers are very close. Among other aspects, this correlation provides credibility to the register file power numbers reported by PowerMeter. It is noted that this is the power consumption for roughly five (5) read and three (3) write accesses. With this in mind, the power consumption is about 20 mW/access.

This register file is designed to fit into a 600 MHz pipeline. However, it has been found in some cases that the delay through the register file is a little more than half of a cycle. In fact, it is the equivalent of a register file with a clock-to-Q time of about 900 ps.

For comparison, in the TSMC65LP process, a 8×64 SRAM with 1 read/1 write port generated by the TSMC memory compiler has an area 0.012 mm² and a current draw of about 8 μA/access. Based on this SRAM, four 8×256 register files would have a total area of about 0.19 mm². When operating at 600 MHz, the power per access of this structure would be 23 mW.

Turning to specific embodiments contemplated, the invention includes a processor register file for a multi-threaded processor with T threads, having N b-bit wide registers. Each of the registers includes a b-bit master latch, T b-bit slave latches connected to the master latch, and a slave latch write enable connected to the slave latches. The master latch is not opened at the same time as the slave latches. In addition, only one of the slave latches is enabled at any given time. As should be apparent to those skilled in the art, T, N, and b are all integers.

It is also contemplated that the register file of the invention is designed such that the master latch opens when a clock signal reaches a predetermined clock level. In this embodiment, it is contemplated that the slave latches open when a slave latch enable signal reaches a predetermined slave latch enable level that is complimentary to the predetermined clock level.

The invention also is contemplated to encompass an embodiment where the master latch writes in response to a write enable signal that is separate from the slave latch enable signal. Here, the master latch is open only if the clock signal reaches the predetermined clock level and the write enable signal is true.

The register file also may be configured such that the write enable signal clock-gates the predetermined clock level.

In addition, the slave latch enable signal may gate the slave latch enable level that is complimentary to the predetermined clock level.

An additional embodiment of the register file contemplates the inclusion of additional features such as R read ports. The read ports include N T-to-1 b-bit wide slave muxes connected to the slave latches that select ones from outputs of the slave latches for each register. The read ports also include R N-to-1 b-bit wide muxes connected to the slave muxes that select ones from outputs of the slave muxes. As may be appreciated, R is an integer.

In another embodiment contemplated to fall within the scope of the invention, a processor register file for a multi-threaded processor is provided. The processor register file has T threads, N b-bit wide registers, and W write ports. The processor register file includes W b-bit master latches and N slave latch groups. The slave latch groups encompass T b-bit slave latches and are connected to the master latches. The register file also includes N W-to-1 select muxes connected to the slave latch groups, one for each of the slave latch groups. The select muxes select from the master latches and generate outputs connected to corresponding ones of the slave latches in the slave latch groups and their corresponding selects. The register file also includes N thread latch enables, one for each of the slave latch groups, such that each of the thread latch enables enables at most one of the latches in the corresponding group. Associated ones of the master latches and slave latches are not opened at the same time.

Another contemplated embodiment of the invention encompasses a processor register file for a multi-threaded processor with T threads, having N b-bit wide registers, W write ports, and a loop-back write port. The register file includes W b-bit regular master latches and N slave latch groups, encompassing T b-bit slave latches, connected to the regular master latches. The register file also includes N b-bit loop-back master latches, with one loop-back master latch corresponding to each slave latch group. In addition, the register file includes N W+1-to-1 b-bit select muxes, one for each slave latch group. The select muxes select from the regular master latches and the loop-back master latches and generate output connected to each of the b-bit slave latches in a corresponding one of the slave latch groups. Next, the register file includes N T-to-1 b-bit loop-back muxes, one for each of the slave latch groups. One from the loop back muxes selects between the slave latches in one from the slave latch groups and writes to a corresponding loop-back latch. The register file also includes N thread latch enables, one for each of the slave latch groups. Each of the thread latch enables enables at most one of the slave latches in a corresponding one from the slave latch groups. In this arrangement, master and slave latches are never open at the same time. As should be apparent, T, N, b, and W are all integers.

In a variation, it is contemplatd that a first additional logic is positioned between at least one loop-back master latch and at least one select mux.

It is contemplated that the first additional logic may be adapted to select from the loop-back master latches and the regular master latches to establish a W+1 b-bit input for at least one of the select muxes.

In another contemplated variation, a second additional logic may be placed between at least one loop-back mux and at least one loop-back master latch.

The second additional logic may be adapted to select from an output of multiple ones of the loop-back muxes to form the N b-bit inputs to the loop-back master latches.

As should be apparent to those skilled in the art, there are numerous other variations and equivalents of the embodiment described herein that may be employed without departing from the scope of the invention. Those equivalents and variations are intended to fall within the scope of the invention.

What is claimed is:

1. A processor register file for a multi-threaded processor with T threads, having N b-bit wide registers, where each register comprises:
a b-bit master latch;
a plurality, T, of b-bit slave latches connected to the master latch; and
a slave latch write enable connected to the plurality of slave latches;
wherein the master latch is not opened at the same time as the plurality of slave latches,
wherein only one of the plurality of slave latches is enabled at any given time, and
wherein T, N, and b are all integers.

2. The register file of claim 1, wherein:
the master latch opens when a clock signal reaches a predetermined clock level; and
the slave latches open when a slave latch enable signal reaches a predetermined slave latch enable level that is complimentary to the predetermined clock level.

3. The register file of claim 2, wherein:
the master latch writes in response to a write enable signal that is separate from the slave latch enable signal; and
the master latch is open only if the clock signal reaches the predetermined clock level and the write enable signal is true.

4. The register file of claim 3, wherein the write enable signal clock-gates the predetermined clock level.

5. The register file of claim 2, wherein the slave latch enable signal gates the slave latch enable level that is complimentary to the predetermined clock level.

6. The register file of claim 1, further comprising:
a plurality, R, of read ports comprising
a plurality, N, of T-to-1 b-bit wide slave muxes connected to the plurality of slave latches that select ones from outputs of the plurality of slave latches for each register; and
a plurality, R, of N-to-1 b-bit wide muxes connected to the plurality of slave muxes that select ones from outputs of the plurality of slave muxes,
wherein R is an integer.

7. A processor register file for a multi-threaded processor with T threads, having N b-bit wide registers, and a plurality, W, of write ports, comprising:
a plurality, W, of b-bit master latches;
a plurality, N, of slave latch groups, comprising a plurality, T, of b-bit slave latches, connected to the plurality of master latches; and
a plurality, N, of W-to-1 select muxes connected to the plurality of slave latch groups, one for each of the plurality of slave latch groups, wherein the plurality of select muxes select from the plurality of master latches and generate outputs connected to corresponding ones of the plurality of slave latches in the plurality of slave latch groups and their corresponding selects; and
a plurality, N, of thread latch enables, one for each of the plurality of slave latch groups, such that each of the plurality of thread latch enables enables at most one of the plurality of latches in the corresponding group,
wherein associated ones of the plurality of master latches and slave latches are not opened at the same time.

8. The register file of claim 7, wherein:
the master latches open when a clock signal reaches a predetermined clock level; and
the slave latches open when a slave latch enable signal reaches a predetermined slave latch enable level that is complimentary to the predetermined clock level.

9. The register file of claim 8, wherein:
the master latches write in response to a write enable signal that is separate from the slave latch enable signal; and
the master latches are open only if the clock signal reaches the predetermined clock level and the write enable signal is true.

10. The register file of claim 9, wherein the write enable signal clock-gates the predetermined clock level.

11. The register file of claim 8, wherein the slave latch enable signal gates the slave latch enable level that is complimentary to the predetermined clock level.

12. The register file of claim 7, further comprising:
a plurality, R, of read ports comprising
a plurality, N, of T-to-1 b-bit wide slave muxes connected to the plurality of slave latches that select ones from outputs of the plurality of slave latches for each register; and
a plurality, R, of N-to-1 b-bit wide muxes connected to the plurality of slave muxes that select ones from outputs of the plurality of slave muxes,
wherein R is an integer.

13. A processor register file for a multi-threaded processor with T threads, having N b-bit wide registers, a plurality, W, of write ports, and a loop-back write port, comprising:
a plurality, W, of b-bit regular master latches;
a plurality, N, of slave latch groups, comprising a plurality, T, of b-bit slave latches, connected to the plurality of regular master latches;
a plurality, N, of b-bit loop-back master latches, with one loop-back master latch corresponding to each slave latch group;
a plurality, N, of W+1-to-1 b-bit select muxes, one for each slave latch group, wherein the plurality of select muxes select from the regular master latches and the loop-back master latches and generate output connected to each of the plurality of b-bit slave latches in a corresponding one of the plurality of slave latch groups;
a plurality, N, of T-to-1 b-bit loop-back muxes, one for each of the plurality of slave latch groups, wherein one from the plurality of loop back muxes selects between the plurality of slave latches in one from the plurality of slave latch groups and writes to a corresponding loop-back latch; and
a plurality, N, of thread latch enables, one for each of the plurality of slave latch groups, wherein each of the thread latch enables enables at most one of the plurality of slave latches in a corresponding one from the plurality of slave latch groups;
wherein master and slave latches are never open at the same time, and
wherein T, N, b, and W are all integers.

14. The register file of claim 13, wherein:
the regular master latches open when a clock signal reaches a predetermined clock level; and
the slave latches open when a slave latch enable signal reaches a predetermined slave latch enable level that is complimentary to the predetermined clock level.

15. The register file of claim 14, wherein:
the regular master latches write in response to a write enable signal that is separate from the slave latch enable signal; and
the regular master latches are open only if the clock signal reaches the predetermined clock level and the write enable signal is true.

16. The register file of claim 15, wherein the write enable signal clock-gates the predetermined clock level.

17. The register file of claim 14, wherein the slave latch enable signal gates the slave latch enable level that is complimentary to the predetermined clock level.

18. The register file of claim 13, further comprising:
a plurality, R, of read ports comprising
a plurality, N, of T-to-1 b-bit wide slave muxes connected to the plurality of slave latches that select ones from outputs of the plurality of slave latches for each register; and
a plurality, R, of N-to-1 b-bit wide muxes connected to the plurality of slave muxes that select ones from outputs of the plurality of slave muxes,
wherein R is an integer.

19. The register file of claim 13, further comprising a first additional logic between at least one loop-back master latch and at least one select mux.

20. The register file of claim 19, wherein the first additional logic is adapted to select from the plurality of loop-back master latches and the plurality of regular master latches to establish a W+1 b-bit input for at least one of the plurality of select muxes.

21. The register file of claim 13, further comprising a second additional logic between at least one loop-back mux and at least one loop-back master latch.

22. The register file of claim 21, wherein the second additional logic is adapted to select from an output of multiple ones of the plurality of loop-back muxes to form the N b-bit inputs to the plurality of loop-back master latches.
